(19) United States
(12) Patent Application Publication
(10) Pub. No.: US 2021/0384700 A1
(43) Pub. Date: Dec. 9, 2021

(54) Method for Processing a Laser Device

(71) Applicant: IMEC VZW, Leuven (BE)

(72) Inventors: Charles Caer, Uccle (BE); Philippe Soussan, Wavre (BE); Deniz Sabuncuoglu Tezcan, Herent (BE); Gauri Karve, Tervuren (BE); Yunlong Li, Leuven (BE)

(21) Appl. No.: 17/340,351

(22) Filed: Jun. 7, 2021

(30) Foreign Application Priority Data
Jun. 9, 2020 (EP) 20178973.2

(51) Int. Cl. H01S 5/026; H01S 5/30; H01S 5/042

(52) U.S. Cl. CPC H01S 5/026; H01S 5/04254; H01S 5/3013

(57) ABSTRACT

The disclosure relates to a method for processing a laser device, for example a III-V on silicon laser, including: providing a carrier substrate; forming a grating structure on the carrier substrate, wherein the grating structure delimits a cavity on a surface of the carrier substrate; placing a die in the cavity and bonding the die to the carrier substrate, wherein the die comprises an active region including a III-V semiconductor material; transferring the die from the carrier substrate to a silicon substrate by bonding an exposed side of the die to the silicon substrate and subsequently debonding the carrier substrate from the die; and forming a photonic structure, for example a silicon waveguide, coupled to the die.

### CROSS-REFERENCE TO RELATED APPLICATIONS

The present application is a non-provisional patent application claiming priority to European Patent Application No. 20178973.2, filed Jun. 9, 2020, the contents of which are hereby incorporated by reference.

### FIELD OF THE DISCLOSURE

The present disclosure relates to a method for processing a laser device and to a laser device, in particular a III-V on silicon laser co-integrated with photonics devices such as waveguides.

### BACKGROUND

The term silicon photonics refers to photonic systems and circuits based on silicon, for instance, silicon-based chips for optical data transmission. Since silicon is not well suited for light emission, it is desirable to integrate light emitting dies made of other more suitable semiconductor materials, especially III-V materials, on silicon substrates. A laser device with a III-V die on a silicon substrate is referred to as a III-V on silicon laser.

However, the integration of such a III-V die on the silicon substrate is difficult and one of the key challenges of silicon photonics. Existing techniques are either relying on external III-V die assembly such as flip-chip bonding, III-V on silicon hetero-epitaxy or heterogeneous wafer/die bonding. However, each of these approaches has its own drawbacks.

External III-V die assembly is somewhat easy and is commercially available. It, however, suffers from low alignment tolerances associated with high packaging costs, coupling losses, and unwanted back-reflections in the III-V die.

III-V on silicon heteroepitaxy is still mostly in development. The main drawback resides in the need for growing very thick buffer layers in specific areas to filter dislocations. The thick layers, however, may prevent coupling to silicon photonic devices. Currently this approach also does not allow a large light output.

Heterogeneous integration of III-V wafers/dies is another approach that allows a III-V layer transfer to silicon. The main drawbacks are the thermal isolation of the III-V from the silicon substrate by oxides, degrading laser performance and reliability, and limited throughput caused by the pick and place process used for fabrication that requires a high alignment accuracy with the underlying photonic devices.

### SUMMARY

According to a first aspect, the present disclosure relates to a method for processing a laser device, in particular a III-V on silicon laser, comprising:

providing a carrier substrate;

forming a grating structure on the carrier substrate, wherein the grating structure delimits a cavity on a surface of the carrier substrate;

placing a die in the cavity and bonding the die to the carrier substrate, wherein the die comprises an active region from at least one III-V semiconductor material;

transferring the die from the carrier substrate to a silicon substrate by bonding an exposed side of the die to the silicon substrate and subsequently debonding the carrier substrate from the die;

forming at least one material layer on the die so that the die is fully covered; and

forming a photonic structure, for example a structure formed from a material with high refractive index, such as a silicon waveguide, coupled to the die.

No placing of individual III-V dies and active alignment of their laser output regions on the silicon substrate is required, which can simplify the processing of the laser device and allows for a high throughput.

For example, the gain region and the photonics structure are directly aligned by a high accuracy lithographic process.

The active region can comprise a plurality of different materials, in particular arranged as a heterostructure. For example, the active region of the die comprises an indium gallium aluminum arsenide (InGaAlAs), an indium gallium nitride (InGaN) and/or an indium arsenide (InAs) material. The active region can comprise quantum dots and/or multiple quantum wells (MQWs). Other III-V and III-N substrates can be comprised in the active region, e.g. gallium nitride (GaN), gallium arsenide (GaAs), or gallium antimonide (GaSb).

For example, the die is bonded to the carrier substrate with the active region pointing towards the carrier substrate, and a die-substrate pointing upwards and away from the carrier substrate.

The carrier substrate can be a silicon or a glass substrate. For example, the carrier substrate is a wafer.

The at least one material layer can comprise a silicon dioxide (SiO₂) layer and/or a silicon nitride (Si₃N₄) layer.

The photonic structure can be a waveguide. Alternatively, the photonic structure can be a photonic crystal, a quantum wire, a quantum dot, or any other structure suitable for confining light.

In an embodiment, the photonic structure is made of a high refractive index material, such as silicon or silicon nitride (Si₃N₄). In examples, the material of the photonic structure has a higher refractive index than materials directly surrounding the photonic structure, such that light can efficiently be confined and/or guided in the photonic structure.

The photonic structure can be arranged coupled to the active region such that light that is generated in the active region couples to the photonic structure, for example by means of evanescent coupling.

In an embodiment, the grating structure on the carrier substrate is formed by bonding a structured substrate to the surface of the carrier substrate, wherein the structured substrate comprises a through hole.

Thus, within examples, the grating structure can be formed in an efficient way.

The structured substrate can be a structured silicon wafer covered by an SiO₂ layer. After bonding the structured substrate to the carrier substrate, the through hole of the structured substrate can form the cavity for the die.

In an embodiment, after placing the die in the cavity, the cavity is at least partially filled up by a buffer material, for example, an oxide.

Gaps in the cavities, in particular between the dies and the cavity walls, can be prevented. In particular, filling any gaps in the cavity can allow processing the substrate in later steps, for instance grinding the die and grating structure.

The buffer can be formed by a spin-on-glass process and can be annealed in a subsequent step to form SiO₂.

In an embodiment, the grating structure is transferred together with the die from the carrier substrate to the silicon substrate.

The die can be transferred efficiently by a single bonding/debonding process. In particular, if the grating structure forms several cavities on the carrier substrate, wherein a respective die is arranged in each cavities, then these multiple dies can be transferred simultaneously together with the grating structure without needing to individually pick-and-place and align each die on the silicon substrate.

In an embodiment, prior to transferring the die and the grating structure to the silicon substrate, the die and the grating structure are grinded and/or polished.

An interface for bonding the dies and grating structure to the silicon substrate can be formed. Furthermore, the thinning of the dies that are subsequently bonded to the silicon substrate can enhance heat dissipation from the active region and, therefore, reliability.

The die and/or grating structure can be polished by means of chemical-mechanical polishing (CMP).

In an embodiment, the die comprises a top structure and a base structure that delimit the active region, wherein the top and base structure each comprise at least one III-V or III-N material layer, in particular an indium phosphide (InP), a gallium nitride (GaN), a gallium arsenide (GaAs), an indium arsenide (InAs) or a gallium antimonide (GaSb) layer, wherein the base structure is bonded to the silicon substrate, for example via at least one bonding layer.

For example, the base structure of the die comprises a die-substrate on which the active region is arranged, and which is bonded to the silicon substrate.

In an embodiment, the method further comprises:

following transferring the die to the silicon substrate, structuring the die by a lithographic process to define a dimension of the active region and/or to expose the base structure of the die.

A precise alignment of the die, in particular the active region, can be realized. In this way, misalignments of the die that result from inaccuracies when placing the die in the cavity can be compensated.

Defining a dimension of the active region may comprise reducing its overall size and centering the active region, so that the exact position and size of the active region on the silicon substrate is defined for later processing steps. In particular, the lithographic process can be carried out by an advanced lithographic tool, such as a 193 nm DUV stepper. Thus, no active alignment of individual dies on the silicon substrate needs to be carried out.

In an embodiment, the method further comprises the steps of:

forming contact pads on the top structure and the exposed base structure of the die; and

following forming of the at least one material layer coupled to the die, electrically contacting the contact pads by etching vias into the at least one material layer and filling the vias with a metal.

In examples, electrical contact active region can be generated efficiently.

For example, the contact pads are formed from a CMOS compatible material. The contact pads can form Ohmic contacts on the die.

In an embodiment, the photonic structure is a silicon waveguide.

In an embodiment, the photonic structure is formed by depositing a further material layer, in particular a silicon layer, coupled to the die and lithographic structuring the further material layer.

The photonic structure can be generated efficiently and with high alignment accuracy to the active region of the die. For example, the further material layer is a silicon layer.

In an embodiment, a further photonic structure, for example a silicon nitride waveguide, is formed coupled to the die, wherein the further photonic structure is arranged coupled to or next to the photonic structure.

A photonic structure can be provided for forwarding the light generated by the III-V, for instance to a photonic circuit.

The further photonic structure can be formed from LPCVD silicon nitride that can, for instance, be applied by wafer bonding. The further photonic structure can alternatively be formed from a low loss material, such as niobium oxide or tantalum pentoxide.

In an embodiment, the method comprises the further steps of:

forming a recess at a backside of the silicon substrate below the die; and

coating the backside of the silicon substrate with a metallic material.

A heat dissipating structure can be formed on the backside of the silicon substrate, for dissipating heat away from the III-V die.

For example, prior to forming the recess, the silicon substrate is thinned down from the backside. This supports dissipating heat away from the active region.

In an embodiment, the grating structure delimits a plurality of cavities on the surface of the carrier substrate, wherein one of a plurality of dies is placed in each respective cavity and bonded to the carrier substrate, wherein the plurality of dies are transferred from the carrier substrate to the silicon substrate simultaneously.

In this way, the process can allow forming a plurality of laser devices or a laser device with a plurality of dies simultaneously. The dies and the grating structures can be transferred simultaneously from the carrier substrate to the silicon substrate. The at least one material layer can be formed coupled to the dies, so that all dies are fully covered. Further, a respective photonic structure, e.g. a waveguide, can be formed coupled to each die.

A laser device formed with the method of the first aspect typically shows clear “fingerprints” of that method. By placing the die in a cavity on a carrier substrate, transferring the dies to a silicon wafer, for example together with the grating structure which forms the cavity, and coating the transferred die with at least one material layer, the die is fully embedded on the silicon substrate. In particular, the die is fully covered by the material layer and no area of the die is exposed.

According to a second aspect, the present disclosure relates to a laser device, in particular a III-V on silicon laser, comprising: a silicon substrate, a die that is arranged in a cavity on the silicon substrate, wherein the die comprises an active region from at least one III-V semiconductor material, wherein the die is bonded to the silicon substrate, wherein the die is fully covered by at least one material layer, and wherein the laser device further comprises at least one photonic structure, for example a silicon waveguide and/or a silicon nitride waveguide, that is arranged coupled to the die.

Thus, a III-V laser on a silicon substrate can be provided. In particular, the III-V active region is fully embedded such that the laser device can be further processed, e.g. by lithographic processing.

In an embodiment, the die comprises a top and a base structure that delimit the active region, wherein the top and base structure each comprise at least one III-V or III-N material layer, in particular an indium phosphide (InP), a gallium nitride (GaN), a gallium arsenide (GaAs), an indium arsenide (InAs), or a gallium antimonide (GaSb) layer, wherein the base structure is bonded to the silicon substrate, for example via at least one bonding layer.

Gaps in the cavities, in particular between the dies and the cavity walls, can be prevented.

In an embodiment, the laser device comprises a plurality of dies, wherein each of the plurality of dies is arranged in a respective cavity on the silicon substrate.

The above description with regard to the method for processing the laser device according to the first aspect of the present disclosure is correspondingly valid for the laser device according to the second aspect of the present disclosure.

### BRIEF DESCRIPTION OF THE FIGURES

The above, as well as additional, features will be better understood through the following illustrative and non-limiting detailed description of example embodiments, with reference to the appended drawings.

FIG. 1 shows a method for processing a laser device, according to an example.

FIG. 2 shows a method for processing a laser device, according to an example.

FIG. 3 shows a method for processing a laser device, according to an example.

FIG. 4 shows a method for processing a laser device, according to an example.

FIG. 5 shows a method for processing a laser device, according to an example.

FIG. 6 shows a method for processing a laser device, according to an example.

FIG. 7 shows a method for processing a laser device, according to an example.

FIG. 8 shows a method for processing a laser device, according to an example.

FIG. 9 shows a method for processing a laser device, according to an example.

FIG. 10 shows a method for processing a laser device, according to an example.

FIG. 11 shows a method for processing a laser device, according to an example.

FIG. 12 shows a method for processing a laser device, according to an example.

FIG. 13 is a cross sectional view of a laser device, according to an example.

FIG. 14 shows a die, according to an example.

FIG. 15 shows a die, according to an example.

FIG. 16 shows a die, according to an example.

FIG. 17 shows a die, according to an example.

FIG. 18 includes a perspective view and a cross sectional view of a laser device, according to an example.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

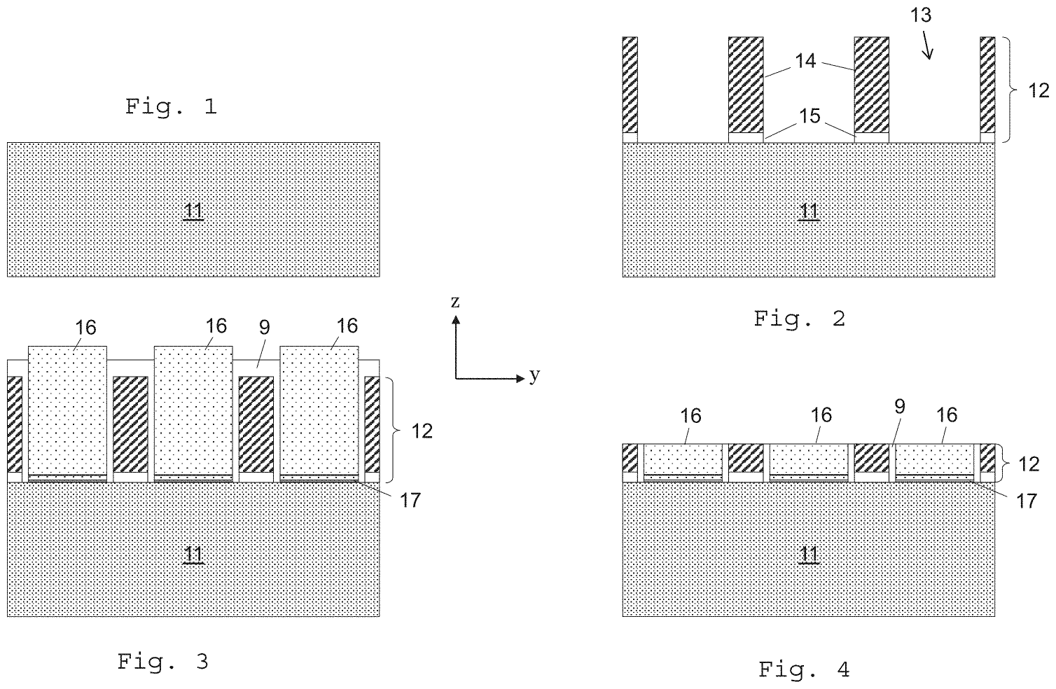

FIGS. 1-12 show steps of a method for processing a laser device, in particular a III-V on silicon laser, according to an embodiment.

The method can be used to process a plurality of laser devices in parallel, each laser device comprising one or more dies 16 with III-V active regions. For instance, FIGS. 1-12 either show a processing of three laser devices each having one die 16, or of a single laser device having three or more dies 16. For the sake of clarity, in the following the method is explained with reference to laser devices having one die, the same method steps can apply to all other laser devices and/or to further dies/photonic structures of the laser device.

The method comprises, as shown in FIG. 1, providing a carrier substrate 11. The carrier substrate 11 can be a glass or a silicon wafer. In particular, the substrate 11 is a temporary carrier wafer.

As shown in FIG. 2, the method comprises forming a grating structure 12 on the carrier substrate 11, wherein the grating structure 12 delimits a cavity 13 on the surface of the carrier substrate 11.

The grating structure 12 can be formed by bonding a structured substrate to the surface of the carrier substrate 11. The structured substrate can comprise a silicon or InP base structure 14 that is covered by an oxide layer 15. The structured substrate can be bonded to the carrier substrate 11 via the oxide layer 15. Further, the structured substrate can comprise at least one through hole, which forms the cavity 13 on the carrier substrate 11. In particular, the structured substrate can be a silicon or InP wafer that is oxidized, etched, and thinned down to form open cavities on the carrier substrate 11.

The oxide layer 15 of the structured substrate can have a thickness of several microns. The structured substrate can grinded after bonding it to the carrier substrate 11.

As shown in FIG. 3, a die 16 can be placed in the cavity 13 and bonded to the carrier substrate 11. Thereby, the active region 17 of the die 16 is facing down, towards the carrier substrate 11. In other words, the cavity 13 defines a pocket that can be populated with the III-V die 16.

The die 16 comprises a top and a base structure that delimit the active region 17, wherein the top structure is bonded to the carrier substrate 11, such that the base structure faces up and away from the carrier substrate 11. For example, the base structure of the die 16 comprises a die-substrate on which the active region 17 is arranged.

In a subsequent step, also shown in FIG. 3, the cavity 13 can be filled up by a buffer material 9, in particular by a spin-on-glass, that is cured and/or annealed to form an oxide.

Subsequently, as shown in FIG. 4, the die 16 and the grating structure 12 can be thinned down by grinding and/or polishing, in particular by means of chemical mechanical polishing (CMP), in order to generate a surface that is suitable for the following bonding step. For example, the die 16 and grating structure 12 are thinned down to a few microns. In particular, the III-V die 16 and silicon planarization enables heterogeneous III-V material integration.

As shown in FIG. 5, the method further comprises bonding the thinned die and grating structure to a silicon substrate 18, for example via a bonding layer. The bonding layer can be a SiO₂ layer.

In a subsequent step, shown in FIG. 6, the carrier substrate 11 is debonded from the die 16 and grating structure 12. Consequently, the die 16 on the silicon substrate 18 is arranged in such a way that the active region 17 is facing up and away from the silicon substrate 18. The die 16 is bonded to the silicon substrate 18 by its base structure.

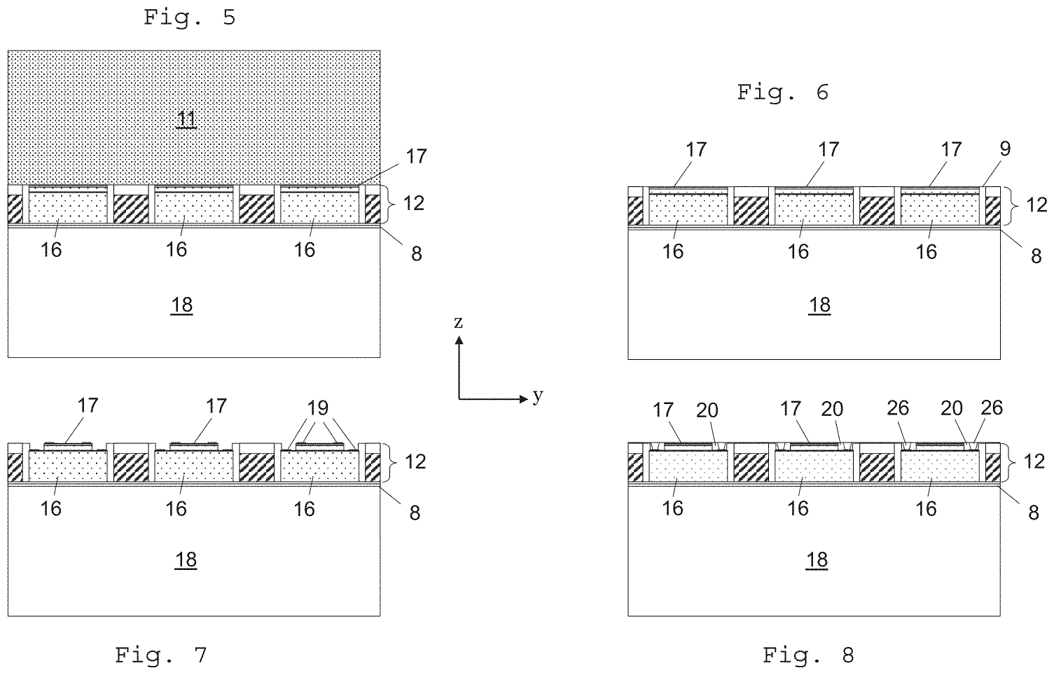

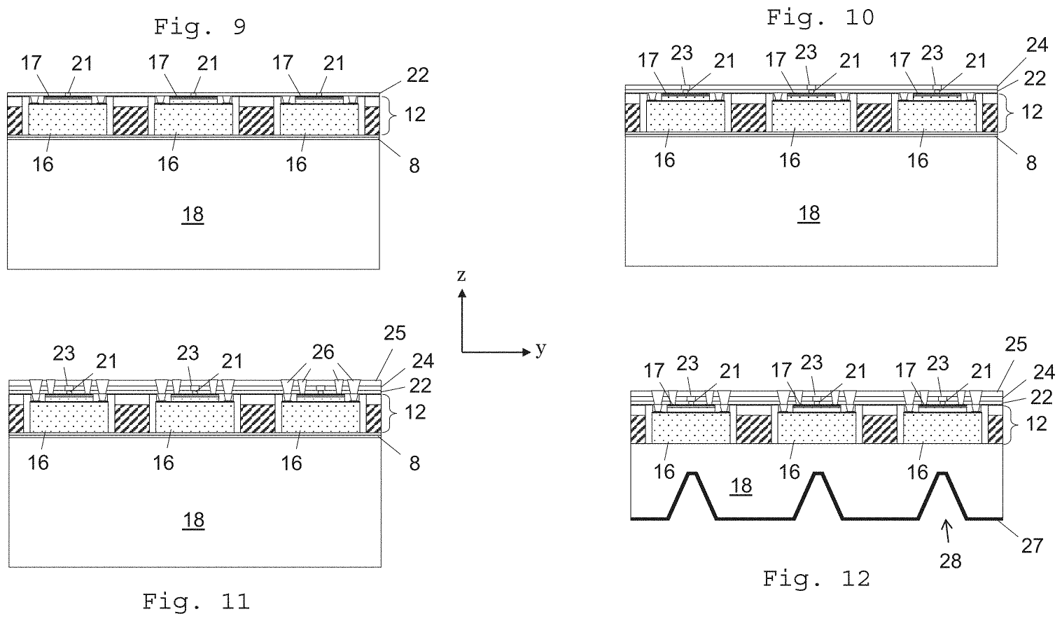

In a subsequent step, shown in FIG. 7, the die 16 can be structured by a lithographic process to define a dimension and exact position of the active region 17 and/or to expose the base structure of the die 16. In particular, the active region 17 of the die 16 forms a III-V mesa.

For example, the lithographic structuring of the active region 17 is carried out by a high accuracy scanner or stepper, e.g., a 193 nm DUV stepper or another advanced CMOS fab tool. This allows for a precise definition of the III-V MESA structure of the lasers (active region 17) and the respective positioning of the waveguide 21, 23 to the mesa with <100 nm precision (see FIGS. 9-11). In particular, when fabricating several laser devices in parallel, this lithographic structuring can allow a precise alignment of the active regions 17 of all dies 16 on the silicon substrate 18 in a single step. Thereby, thick active layers (>10 μm), which can be useful for high power lasers can be structured to accurately align the laser output region to a photonic circuit.

For example, the method further comprises forming contact pads 19 on the top structure and the exposed base structure of the die 16. The contact pads 19 can be formed from a CMOS compatible material, e.g. a CMOS compatible metal.

In a subsequent step, shown in FIG. 8, an oxide layer 20 can be formed on and around the structured die 16. Subsequently, the contact pads 19 are electrically contacted by etching vias 26 in the oxide layer 20 and filling the vias 26 with a metallic material, e.g. tungsten (W). The oxide layer 20 can further be planarized to allow deposition of further layers on top.

Subsequently, as shown in FIG. 9, a photonic structure 21 can be formed coupled to the die 16. The photonic structure 21 can be formed by depositing a subsequently lithographic structuring of a material layer, e.g. an amorphous silicon (a-Si) layer.

The photonic structure 21 can be a waveguide, in particular a silicon waveguide. For example, the waveguide extends along an x-direction, perpendicular to the cross sectional view of the silicon substrate 18 and die 16 in the y-z-direction as indicated by the schematic coordinate system.

The method can further comprise a deposition of an oxide layer 22 around the waveguide 21 and a planarization of the waveguide 21 and the oxide layer 22.

As shown in FIG. 10, the method can further comprise forming a further photonic structure, e.g., a further waveguide 23, coupled to the die 16. The further photonic structure can be made of silicon nitride (Si₃N₄) and can be formed by lithographic structuring a silicon nitride layer. The silicon nitride layer can be deposited on the oxide layer 22, e.g. using a Plasma-Enhanced Chemical Vapor Deposition (PECVD) or a Physical Vapor Deposition (PVD) process. Alternatively, the silicon nitride layer can be transferred from a further substrate that is bonded to and, subsequently debonded from the oxide layer 22.

Following the formation of the further photonic structure, a further oxide layer 24 can be formed around the further waveguide 23 and a planarization of the further waveguide 23 and the further oxide layer 24 can be performed.

Subsequently, as shown in FIG. 11, another oxide layer 25 can be deposited on the further oxide layer 24. Finally, vias 26 can be etched in the oxide layer 25 and filled with a metallic material, to electrically contact the contact pads 19.

In particular, the silicon photonics layers 22, 24 and structures 21, 23 are built coupled to the III-V active region 17, potentially enabling high alignment accuracy and high device quality, e.g., on a 200 or 300 mm wafer scale.

In a further step, shown in FIG. 12, the silicon substrate 18 can be thinned and a recess 28 can be formed on the silicon substrate 18 backside below the die 16. The recess 28 can be etched via isotropic etching, e.g., wet etching with potassium hydroxide (KOH), and can form a cavity on the substrate 18 backside. In addition, a metal coating 27, e.g. a copper coating, can be deposited on the backside of the silicon substrate 18. The coated cavity on the backside of the silicon substrate can form a heat spreading structure that supports dissipating heat away from the die 16 and the active region 17.

In particular, the wafer reconstitution method shown in FIGS. 1-12 can enable the realization of hybrid devices through the coupling between the III-V active regions 17 and the photonic layers and structures, e.g. structures 21, 23.

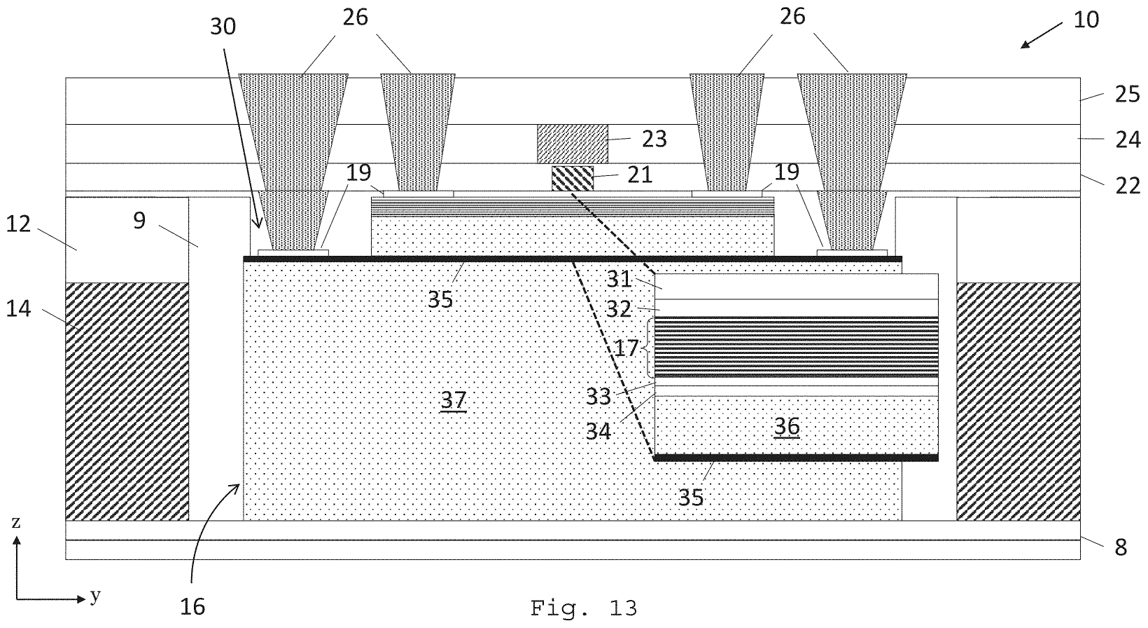

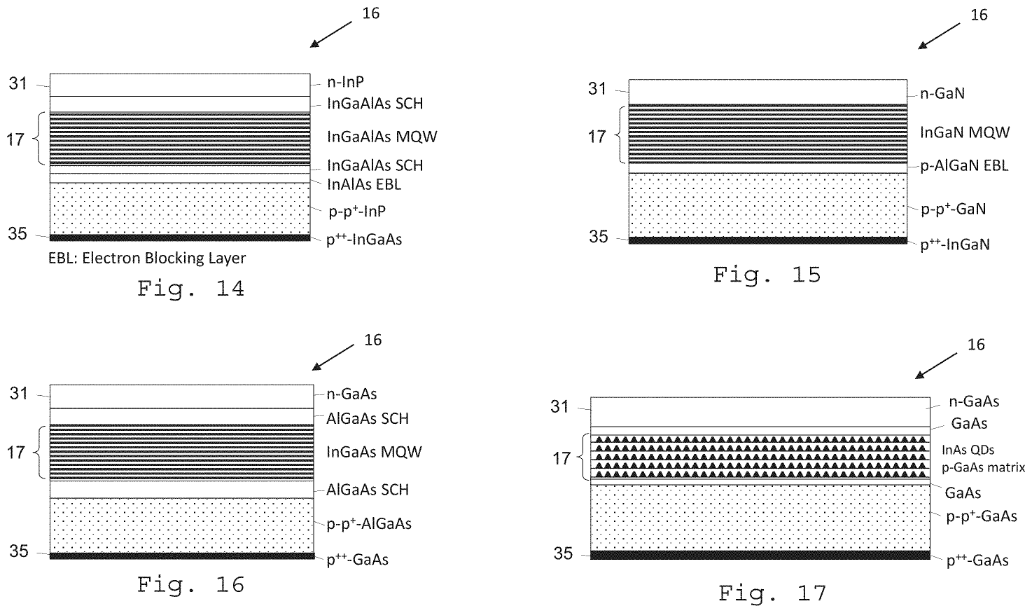

FIG. 13 shows a cross sectional view of a laser device 10 according to an embodiment. In particular, the laser device 10 shown in FIG. 13 was formed by the method depicted in FIGS. 1-12. For example, the laser device 10 is a III-V on silicon laser.

The laser device 10 comprises the silicon substrate (not shown) and the die 16 that is arranged in a cavity 30 on the silicon substrate, wherein the die 16 comprises the active region 17 from at least one III-V semiconductor material. The die 16 is bonded to the silicon substrate, for example by means of at least one bonding layer 8, and is fully covered by at least one material layer 22, 24, 25. The laser device 10 further comprises at least one photonic structure 21, 23, for example a silicon waveguide and/or a silicon nitride waveguide that is arranged coupled to the die 16.

In particular, the cavity 30 on the silicon substrate corresponds to the cavity 13 that is formed on the carrier substrate 11 and transferred to the silicon substrate 18 together with the grating structure 12 and the die 16 during processing of the laser device 10 according to FIGS. 1-12.

For example, the die 16 comprises a top structure and base structure that delimit the active region 17. The top structure can comprise a top layer 31, e.g. an InP layer, that is electrically contacted via the contact pad 19 and a SCH layer 32 that is adjacent to the active region 17.

The base structure can be bonded to the silicon substrate via the bonding layer 8. The base structure can comprise a plurality of different layers 33-36, for instance, a further SCH layer that is adjacent to a bottom side of the active region 17 and EBL layers 34, 35. The base structure can further comprise a die-substrate 37 on which the active region 17 and the layers 33-36 are arranged, and which is bonded to the silicon wafer. The contact pads 19 on the backside of the active region 17 can be arranged on the bottom EBL layer 35.

Top and base structures can comprise III-V or III-N material layers, in particular indium phosphide (InP), gallium nitride (GaN), gallium arsenide (GaAs), indium arsenide (InAs) or gallium antimonide (GaSb) layers. The active region 17 can comprise a III-V stack and/or heterostructure.

The cavity 30 can be formed by the grating structure 12 on the silicon substrate, and can be filled up by the buffer material 9. In particular, the die 16 can be higher than the structured substrate forming the cavity, such that the die protrudes out of the cavity.

Gaps in the cavities, in particular between the dies and the cavity walls, can be prevented.

In an embodiment, the laser device 10 comprises a plurality of dies 16, wherein each of the plurality of dies 16 is arranged in a respective cavity 30 on the silicon substrate.

For example, the die 16 can have a width in y-direction of about 20 μm. The photonic structures 21, 23 coupled to the die 16 can have a height of about 1 μm and the material layers 22, 24, 25 can have a total height of 6-10 μm. The total thickness of the laser device 10 in z-direction can be about 400 μm (including the silicon substrate that is not shown in FIG. 13). These design parameters are just example values, other design parameters can be chosen depending on the requirements and materials.

In particular, the laser device 10 is suitable for integration in various electronic devices, such as tunable III-V on silicon lasers, electro-optic linear modulators, waveguide coupled III-V detectors, high power (>100 MW) sources for sensors, opto-electronic transceivers, spectrometers, or Light Detection and Ranging (LidAR) scanners.

FIGS. 14-17 show schematic diagrams of several dies 16 suitable for the laser device 10 of FIG. 13 according to further embodiments. In particular, FIGS. 14-17 each show an upper section of a die 16 that was formed by a lithographic process, as shown in FIG. 7.

FIG. 14 shows a die with an active region 17 comprising indium gallium aluminum arsenide (InGaAlAs) multiple-quantum-wells (MQW). This active region 17 is, for example, adapted to emit light in the near or mid infrared range, e.g. at 1,550 nm. The die comprises an InP top layer 31.

FIG. 15 shows a die 16 with a gallium nitride (GaN) laser profile, with an active region comprising gallium nitride (InGaN) MQWs. The top layer 31 of the die 16 in FIG. 15 is made of GaN.

FIG. 16 shows a die 16 with a gallium arsenide (GaAs) laser profile, wherein the active region comprises indium gallium arsenide (InGaAs) MQWs.

FIG. 17 shows a die 16 with an InAs quantum dot (QD) laser profile, wherein the active region 17 comprises indium arsenide (InAs) QDs arranged in a p-doted gallium arsenide (p-GaAs) matrix.

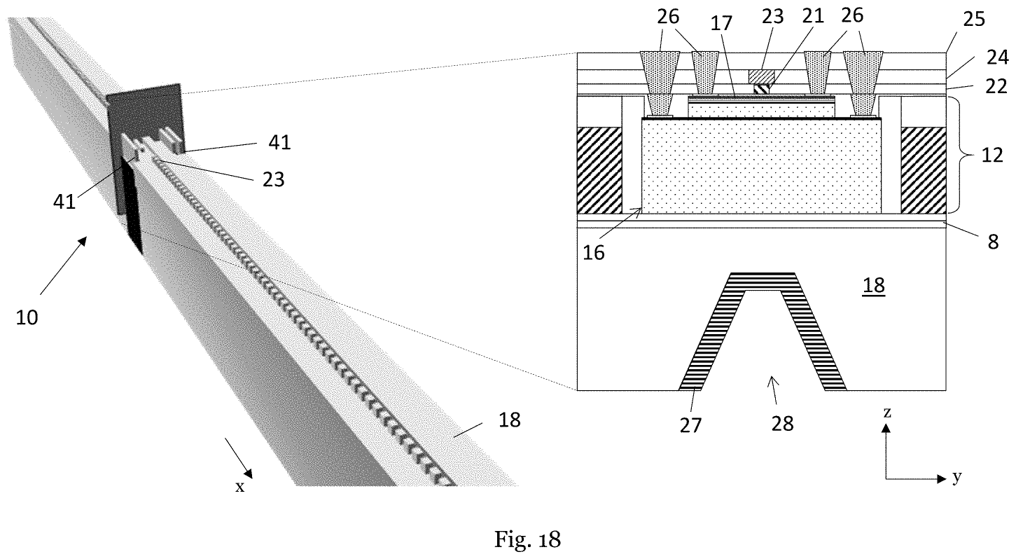

FIG. 18 shows a three dimensional and a cross sectional view of the laser device 10 according to an embodiment.

The three dimensional view shows that the waveguide 23 can propagate along the x-direction perpendicular to y-z-direction of the cross sectional view. For example, light that is generated in the active region 17 of the die 16 can couple into the waveguide 23 by evanescent coupling and propagate along the waveguide 23, e.g. to a photonic circuit.

Furthermore, mirrors 41 can be arranged on the silicon substrate 18 on opposing sides of the die 16 in y-direction, to further confine the light emitted by the active region 17.

All features of all embodiments described, shown and/or claimed herein can be combined with each other.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method comprising:
providing a carrier substrate;
forming a grating structure on the carrier substrate, wherein the grating structure delimits a cavity on a surface of the carrier substrate;
placing a die in the cavity and bonding the die to the carrier substrate, wherein the die comprises an active region including a III-V semiconductor material;
transferring the die from the carrier substrate to a silicon substrate by bonding an exposed side of the die to the silicon substrate and subsequently debonding the carrier substrate from the die; and
forming a photonic structure on the die.

2. The method of claim 1, further comprising forming a material layer on the die, wherein forming the photonic structure comprises forming the photonic structure on the material layer.

3. The method of claim 1, wherein forming the grating structure on the carrier substrate comprises bonding a structured substrate to the surface of the carrier substrate, wherein the structured substrate comprises a through hole.

4. The method of claim 1, further comprising at least partially filling the cavity with a buffer material.

5. The method of claim 4, wherein the buffer material is an oxide.

6. The method of claim 1, wherein transferring the die comprises transferring the grating structure together with the die from the carrier substrate to the silicon substrate.

7. The method of claim 6, further comprising, prior to transferring the die and the grating structure to the silicon substrate, grinding or polishing the die and the grating structure.

8. The method of claim 1, wherein the die comprises a top structure and a base structure that delimit the active region, wherein the top structure and the base structure each comprise a III-V or III-N material layer.

9. The method of claim 8, wherein the III-V or III-N material layer comprises an indium phosphide (InP), a gallium nitride (GaN), a gallium arsenide (GaAs), an indium arsenide (InAs), or a gallium antimonide (GaSb), and wherein the base structure is bonded to the silicon substrate.

10. The method of claim 9, further comprising, following transferring the die to the silicon substrate, structuring the die by a lithographic process to define a dimension of the active region or to expose the base structure.

11. The method of claim 10, further comprising:
forming contact pads on the top structure and the base structure;
forming a material layer on the die; and
electrically contacting the contact pads by etching vias into the material layer and filling the vias with a metal.

12. The method of claim 1, wherein the photonic structure is a silicon waveguide.

13. The method of claim 1, wherein forming the photonic structure comprises depositing a further material layer on the die and lithographically structuring the further material layer.

14. The method of claim 1, further comprising forming a further photonic structure on the die, wherein the further photonic structure is arranged coupled to or next to the photonic structure.

15. The method of claim 1, further comprising:
forming a recess at a backside of the silicon substrate below the die; and
coating the backside of the silicon substrate with a metallic material.

16. The method of claim 1, wherein the grating structure delimits a plurality of cavities on the surface of the carrier substrate, wherein one of a plurality of dies is placed in each respective cavity and bonded to the carrier substrate, wherein the plurality of dies are transferred from the carrier substrate to the silicon substrate simultaneously.

17. A laser device comprising:
a silicon substrate;
a die that is arranged in a cavity on the silicon substrate, wherein the die comprises an active region including a III-V semiconductor material;
wherein the die is bonded to the silicon substrate; and
wherein the laser device further comprises a photonic structure that is arranged coupled to the die.

18. The laser device of claim 17, wherein the die comprises a top structure and a base structure that delimit the active region, wherein the top structure and the base structure each comprise a III-V or III-N material layer, and wherein the base structure is bonded to the silicon substrate.

19. The laser device of claim 17, wherein the cavity is formed by a grating structure on the silicon substrate, and wherein the cavity is filled up by a buffer material.

20. The laser device of claim 17, wherein the laser device comprises a plurality of dies, wherein each of the plurality of dies is arranged in a respective cavity on the silicon substrate.
